(19) United States
(12) Patent Application Publication
(10) Pub. No.: US 2026/0005126 A1
(43) Pub. Date: Jan. 1, 2026

(54) METHODS OF FABRICATING GLASS PANELS TO FORM GLASS CORE PACKAGE STRUCTURES

(71) Applicant: Intel Corporation, Santa Clara, CA (US)

(72) Inventor: Rahul Bhure, Mesa, AZ (US)

(73) Assignee: Intel Corporation, Santa Clara, CA (US)

(21) Appl. No.: 18/757,283

(22) Filed: Jun. 27, 2024

(51) Int. Cl. H01L 23/498; H01L 21/48; H01L 23/15

(52) U.S. Cl. CPC H01L 23/49894; H01L 21/481; H01L 23/15; H01L 23/49827

(57) ABSTRACT

Microelectronic integrated circuit package structures include a package substrate comprising a build-up layer on a glass core, the glass core comprising a first side and a second side opposite the first side. A conductor is within a through glass via (TGV) extending through the glass core. A coating is on a sidewall of at least a portion of the glass core, the coating comprising a polymer material.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

As semiconductor IC packaging architectures continue towards more complex and more compact systems, new material solutions may be used to enable such architectures. One promising candidate for use in packaging substrates is a glass core layer. In such substrates, a glass core is sandwiched between overlying and underlying buildup layers. Electrically conductive vias are provided through the glass core in order to provide electrical coupling between the overlying and underlying buildup layers. Glass cores can be beneficial because they can provide high density vias, provide desirable stiffness to the overall package substrate, and can improve planarity issues at the panel level.

However, glass cores are not without issue. For example, compressive stress vectors applied to the glass core by the buildup layers can result in catastrophic defects, especially at the panel level, such as seware stress defects, which can result in a horizontal splitting of the glass core.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A is a cross-sectional view of a glass handling apparatus comprising a glass panel handling structure, in accordance with some embodiments.

FIG. 1B is a plan view of a glass handling apparatus comprising a glass panel handling structure, in accordance with some embodiments.

FIGS. 1C-1E are cross-sectional views of glass handling apparatus comprising a glass panel handling structure, in accordance with some embodiments.

FIG. 1F is a plan view of a glass handling apparatus comprising a glass panel handling structure, in accordance with some embodiments.

FIG. 2 is a plan view of an IC glass panel, in accordance with some embodiments.

FIGS. 3A-3B are cross-sectional views of glass handling apparatus comprising a glass panel handling structure, in accordance with some embodiments.

FIG. 3C is a plan view of a glass handling apparatus comprising a glass panel handling structure, in accordance with some embodiments.

FIGS. 3D-3E are cross-sectional views of glass handling apparatus comprising a glass panel handling structure, in accordance with some embodiments.

FIGS. 3F-3G are cross-sectional views of IC package structures comprising a polymer coating, in accordance with some embodiments.

FIG. 3H is a spectral graph of a polymer coating, in accordance with some embodiments.

FIGS. 4A-4B are cross-sectional views of glass handling apparatus comprising a glass panel handling structure, in accordance with some embodiments.

FIG. 4C is a plan view of a glass handling apparatus comprising a glass panel handling structure, in accordance with some embodiments.

FIG. 4D is a cross-sectional views of a glass handling apparatus comprising a glass panel handling structure, in accordance with some embodiments.

FIGS. 4E-4F are cross-sectional views of IC package structures comprising a polymer coating, in accordance with some embodiments.

FIG. 4G is a spectral graph of a polymer coating, in accordance with some embodiments.

FIGS. 5A-5B are cross-sectional views of glass handling apparatus comprising a glass panel handling structure, in accordance with some embodiments.

FIG. 5C is a plan view of a glass handling apparatus comprising a glass panel handling structure, in accordance with some embodiments.

FIG. 5D is a cross-sectional view of a glass handling apparatus comprising a glass panel handling structure, in accordance with some embodiments.

FIGS. 5E-5F are cross-sectional views of IC package structures comprising a polymer coating, in accordance with some embodiments.

FIG. 5G is a spectral graph of a polymer coating, in accordance with some embodiments.

FIG. 6A is a cross-sectional view of a glass handling apparatus comprising a glass panel handling structure, in accordance with some embodiments.

FIG. 6B is a plan view of a glass handling apparatus comprising a glass panel handling structure, in accordance with some embodiments.

FIG. 6C is a cross-sectional view of a glass handling apparatus comprising a glass panel handling structure, in accordance with some embodiments.

FIGS. 6D-6E are cross-sectional views of IC package structures comprising a polymer coating, in accordance with some embodiments.

FIGS. 6F-6G are spectral graphs of a polymer coating, in accordance with some embodiments.

FIG. 7 is a cross-sectional view of an IC package structure comprising a polymer coating on sidewalls of a glass core, in accordance with some embodiments.

FIG. 8A-8B illustrate flow charts of processes for the fabrication of IC package structures having a glass core, in accordance with some embodiments.

FIG. 9 is a functional block diagram of an electronic computing device, in accordance with some embodiments of the present disclosure.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

Views labeled “cross-sectional”, “profile” and “plan” correspond to orthogonal planes within a Cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments discussed herein address problems associated with packaging architectures and methods utilizing glass panel processing to form glass core package structures which prevent the formation of stress induced failures. For example, glass core package structures utilizing the glass panel processing methods described herein prevent the formation of stress fractures, such as seware fractures, by utilizing a shock absorber material as an interface between a panel frame and a glass panel during buildup processing. The shock absorber material, such as a polyurethane material, possesses highly tunable mechanical properties. The embodiments described herein enable a higher yield and greater reliability of glass core package structures fabricated according to the various embodiments.

The embodiments herein include methods of processing glass panels by utilizing a glass handling apparatus including a glass handling structure. The glass handling structures may comprise a shock absorbing material which may possess various shapes. In an embodiment, the glass handling structure may comprise a lip wedge cantilever portion, which can be adjusted in order to allow edges of the glass panel to be locked in place between the lip structure during further processing. In another embodiment, the shock absorbing glass handling structure may comprise a slanted wedge shape or an “L” shape to hold edges of the glass panel in place during further processing. In an embodiment, the glass handling structure may comprise a shock absorbing material such as any suitable elastomer, a soft plastic or a polyurethane foam with which to act as a buffer for preventing fractographical defects on the glass panel, as in any of the glass handling structures described herein. Additionally, an adhesive material may be formed on surfaces of the glass panel, the glass handling structure and on portions of the frame.

The architectures described herein may be assembled and/or fabricated with one or more of the features or attributes provided in accordance with various embodiments. A number of different assembly and/or fabrication methods may be practiced to enable the formation of glass core package structures which prevent stress related fractures during processing, according to one or more of the features or attributes described herein.

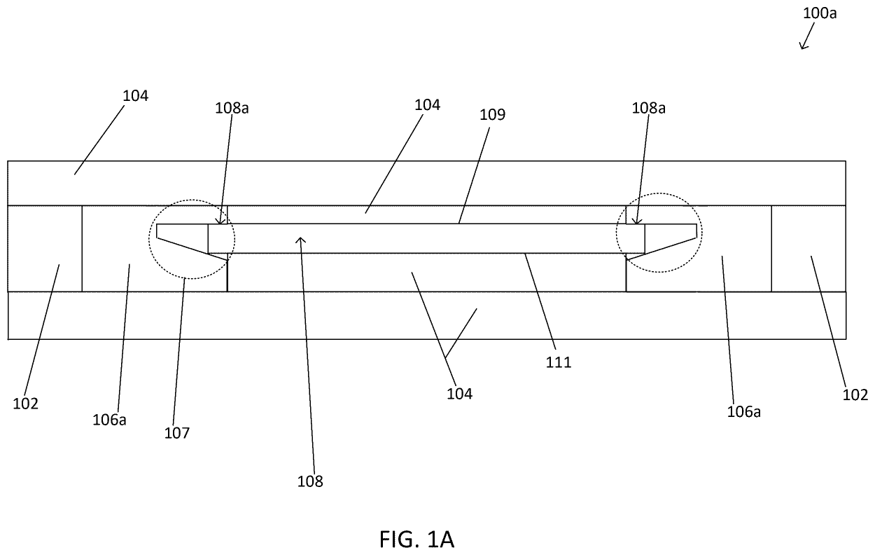

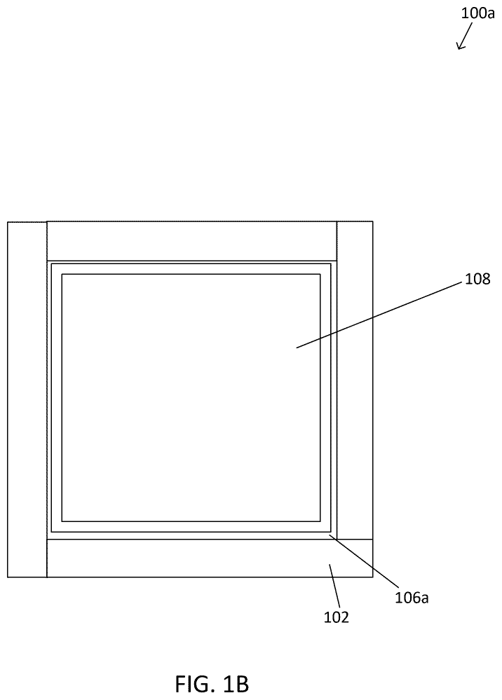

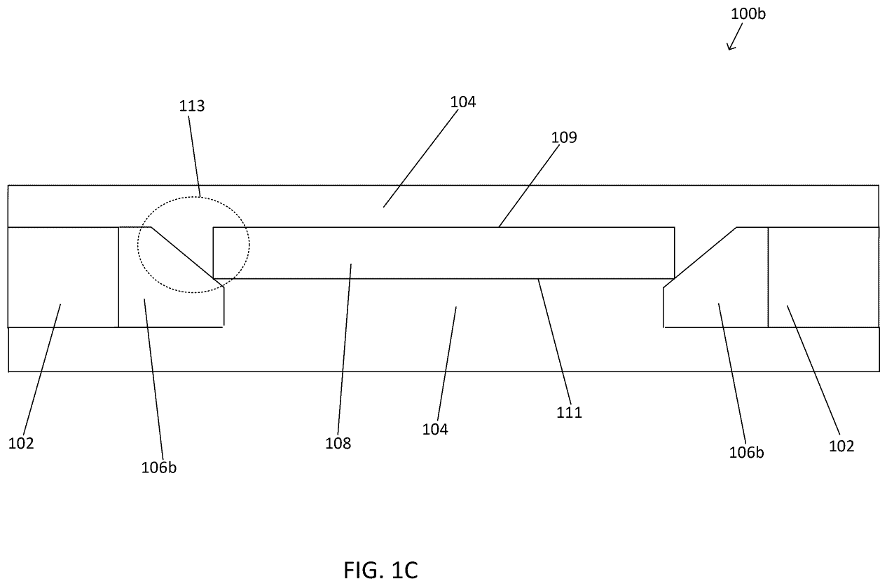

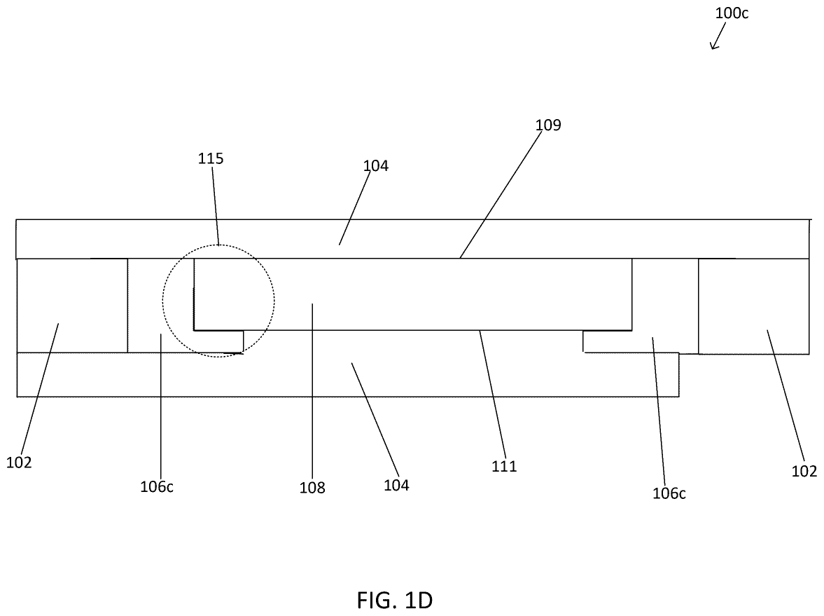

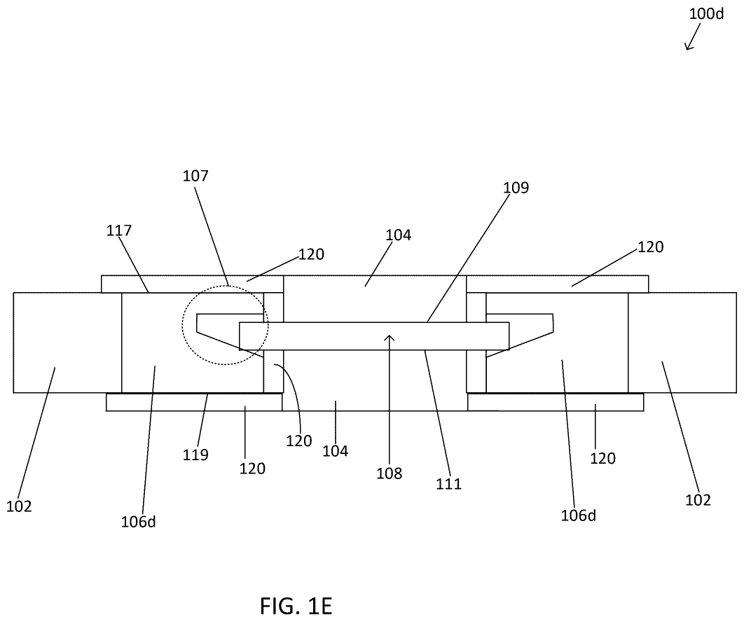

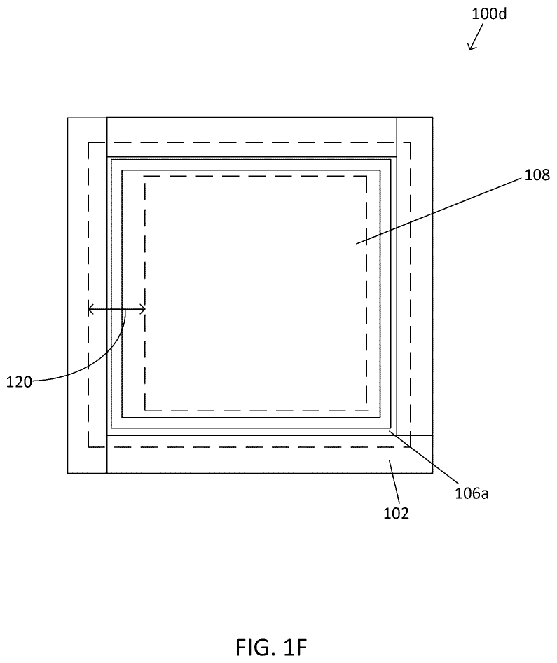

FIGS. 1A-1F illustrate embodiments of utilizing stress mitigation glass panel handling structures to form glass core package structures which prevent edge stress failures. The package structures may be formed utilizing standard IC processing techniques. The methods of fabrication described herein create improved device performance in advanced 2.5D and 3D packaging.

FIG. 1A is a cross-sectional view of a portion of a glass panel handling apparatus 100a comprising a glass panel handling structure 106a which reduces or eliminates glass panel/glass core 108 stress failures. In an embodiment, the glass panel handling structure 106a may comprise a peripheral portion which comprises a lip wedge shape 107. In an embodiment, the glass panel handling structure 106 may comprise a polyurethane (PU) elastomeric material, such as polymeric materials based on diisocyanates, polyols and/or chain extenders. Isocyanates may include Toluene Diisocyanate (TDI), Diphenylmethane Diisocyanate (MDI), Praraphenylene Diisocyanate (PPDI), Toluidine Diisocyanate (TODI), or 1,5-Naphthylene Diisocyanate (NDI). Polyols may include such materials as polyesters, PPG Polyether, PTMEG Polyether, Polycaprolactone, or Polycarbonate. Curatives may comprise such materials as 1,4-Butanediol (BD), 1,3-Propanediol, Ethacure 300, HQEE or MOCA.

The PU material may comprise physical properties which can be tuned for a particular application. For example, physical properties such as strength, stiffness, flexibility, resilience, durability, viscosity and elasticity may be optimized for a particular application. In an embodiment, the polymeric PU which may comprise an elastic polymer. In an embodiment, end portions 108a of a glass panel 108 may be positioned within the lip wedge portion 107 of the glass panel handling structure 106a. The glass panel 108 may comprise a plurality of glass core units, which may be separated from each other during subsequent processing.

In an embodiment, the glass panel 108 may comprise substantially all glass, or may comprise a glass layer. The glass panel 108 may be a solid material with an amorphous crystal structure. More particularly, the glass panel 108 may be any suitable glass formulation that has the necessary mechanical robustness and compatibility with semiconductor packaging manufacturing and assembly processes. For example, the glass panel 108 may comprise aluminosilicate glass, borosilicate glass, alumino-borosilicate glass, silica, fused silica, or the like. In some embodiments, the glass core 108 may include one or more additives, such as, but not limited to, Al2O3, B2O3, MgO, CaO, SrO, BaO, SnO2, Na2O, K2O, SrO, P2O3, ZrO2, Li2O, Ti, and Zn.

More generally, the glass panel 108 may comprise silicon and oxygen, as well as any one or more of aluminum, boron, magnesium, calcium, barium, tin, sodium, potassium, strontium, phosphorus, zirconium, lithium, titanium, and zinc. In an embodiment, the glass panel 108 may comprise at least 23 percent silicon (by weight) and at least 26 percent oxygen (by weight). In some embodiments, the glass panel 108 may further comprise at least 5 percent aluminum (by weight).

In an embodiment, the glass panel 108 may have a thickness (between a first side 109 and second side 111) that is between approximately 50 microns and approximately 2,000 microns, although the thickness may be optimized for the particular application. The glass panel 108 may have a substantially rectangular shape (when viewed from above in a plan view), although, other shapes may also be used for the glass panel 108.

The glass panel handling structure 106a may be coupled to a frame 102. In an embodiment, the frame 102 may comprise a copper clad laminate (CCL) frame. In another embodiment, the frame 102 may comprise a quarter panel frame, and may comprise any suitable material to couple to the glass panel handling structure 106a. The glass panel handling structure 106a provides a highly versatile shock absorber material with highly tunable mechanical properties. The elastomer material of glass panel handling structure 106a may comprise any suitable elastomeric material which prevents stress failures (such as seware stress failures) in the glass panel 108, and additionally prevents such stress fractures in subsequently singulated glass cores within a package substrate.

The glass panel handling structure 106a provides an interface between a metal edge of the frame 102 and the glass panel 108 and acts as a shock absorber. The glass panel handling structure 106a is capable of adjusting its position in three dimensions (3D), due to its elastomeric properties, and can then allow the glass panel 108 to be locked in place. In an embodiment, the glass panel 108 may subsequently be separated from the metal edge of the frame 102 (to be described herein), at the glass panel handling structure 106a/frame 102 interface. In other embodiments, the glass panel separation process may include singulation processes, or any other suitable separation processes.

The glass panel handling apparatus 100a may further accommodate buildup layers 104 on a first side 109 and on a second side 111 of the glass panel 108. Buildup layers 104 may comprise a multiple-layer stack of overlaid sheets of laminated film (e.g., buildup film). Buildup layers 104 materials may include composite epoxies, liquid crystalline polymers and polyimides. Other suitable materials may be employed. In some embodiments, buildup layers 104 are a monolithic block rather than laminated film. Suitable organic or inorganic materials may be employed. Buildup layers 104 may include such materials as FR4 (e.g., epoxy-based laminate), bismaleimide-triaxine, polyimide, silicon, or epoxy resin. buildup layers 104 may comprise organic buildup film or any other dielectric material suitable for electrical packaging. The buildup layers 104 may comprise one or more laminated layers in order to form a structure with a desired thickness. In an embodiment, the buildup layers 104 may comprise electrically conductive features (e.g., pads, traces, vias, etc.) that are fabricated in conjunction with the formation of the buildup layers 104. The buildup layers 104 may include a dielectric material with conductive traces located throughout which may couple another substrate or die. The conductive traces may comprise copper or copper alloys in an embodiment.

FIG. 1B is a top view of the glass panel handling apparatus 100a of FIG. 1A, in accordance with some embodiments. As shown, glass panel 108 is surrounded by the glass panel handling structure 106a which is coupled to the frame 102.

FIG. 1C depicts an embodiment of a glass panel handling apparatus 100b including glass panel handling structure 106b wherein the glass panel handling structure 106b comprises a slant shape or a wedge shape 106b. In an embodiment, the glass panel handling structure 106b may comprise a PU material, which acts as a stress absorber during glass panel 108 processing. In an embodiment, a portion 113 of the glass panel handling structure 106b comprises a slant shape that is at an angle relative to a bottom surface of the glass panel handling structure 106b. The glass panel handling structure 106b holds the glass panel 108 in place prior to forming a buildup layer 104 on first 109 and second 111 sides of the glass panel 108. In an embodiment, the buildup layer 104 may comprise a liquid buildup material which has been cured.

FIG. 1D depicts an embodiment of a glass panel handling apparatus 100c comprising a glass core handling structures 106c wherein a portion 115 of the glass panel handling structure 106c comprises an “L” shape. In an embodiment, the glass panel handling structure 106c may comprise a PU material, which acts as a stress absorber during glass panel 108 processing. In an embodiment, the L shaped portion 115 of the glass panel handling structure 106c is located at a proximal end of the glass panel handling structure 106c. The glass panel handling structure 106c holds the glass panel 108 in place prior to forming a buildup layer 104 on first 109 and second 111 sides of the glass panel 108. In an embodiment, the buildup layer 104 may comprise a liquid buildup material which has been cured.

FIG. 1E depicts an embodiment of a glass panel handling apparatus 100d comprising glass panel handling structure 106a wherein a portion 107 of the glass panel handling structure 106a comprises a lip structure. In an embodiment, the glass panel handling structure 106d may comprise a PU material, which acts as a stress absorber during glass panel 108 processing. In an embodiment, the lip shaped portion 107 of the glass panel handling structure 106a is located at a proximal end of the glass panel handling structure 106a. The glass panel handling structure 106a holds the glass panel 108 in place prior to forming a build up layer 104 on first 109 and second 111 sides of the glass panel 108. In an embodiment, an ultra violet (UV) cured adhesive encapsulant material 120 is on first 117 and second 119 sides of the glass panel handling structure 106a, on adjacent portions of the frame 102, and on portions of the glass panel 108.

In an embodiment, the glass panel handling structure 106a acts as a buffer for preventing fractographical defects on the glass panel 108. The UV curable adhesive 120 can be acrylic based or epoxy based. In an embodiment, the adhesive material 120 may comprise a methylmethacrylate, acrylate, or MMA) and may comprise a resin-based, two-part adhesive comprised of acrylic or methylacrylic polymers. In another embodiment, the adhesive 120 may comprise such materials as glycidyl polyether of a dihydric phenol, filler, a flexibilizer and a curing agent, preferably, a mixture of an amine hardener and a rigidifying tertiary amine catalyst. Enhancement of physical properties of the adhesive material 120 may be obtained by admixing a silane or silicone adhesion promoter.

FIG. 1F is a top view of the glass panel handling apparatus 100d of FIG. 1E, in accordance with some embodiments. As shown, glass panel 108 is surrounded by the glass panel handling structure 106a which is coupled to the frame 102. Adhesive material 120 is located in peripheral regions around the glass panel 108 and on portions of the frame 102 and glass panel handling structure 106a.

FIG. 2 illustrates a glass panel structure (such as the glass panel structures 108 of FIGS. 1A-1F for example. FIG. 2 depicts a top view of a glass panel 201, in accordance with an embodiment. The glass panel 201 may include a plurality of glass package substrate units 210 that are distributed across the glass panel 201. The individual glass units 210 may be provided in a grid-like array. For example, the glass units 210 may be provided in an array that forms four quarter panels, and each quarter panel has twelve individual glass units 210. The number and layout of the glass units 210 within the glass panel 201 may be varied depending on the size of the glass panel 201 and the size of the glass units 210, among other factors. The use of glass panel level processing allows for improved throughput. That is, a plurality of glass units 210 may be fabricated and assembled substantially in parallel with each other. After the glass panel 201 is completed, individual units 210 may be singulated with any suitable process. For example, a saw or other mechanical tool may cut along saw streets between the individual units 210, as well as laser processing may be employed, as is known in the art.

In the illustrated embodiment, the glass units 210 are shown with dashed lines. Dashed lines are used since, at the glass panel 210 level, the individual glass units 210 may not have any distinguishable boundary from each other. For example, the top layer (e.g., buildup layers 211) may be a substantially uniform top surface. In some instances voided regions of the panel 201 (e.g., regions without electrical routing) may be provided along the saw streets between the glass units 210.

The glass panel 201 may comprise a plurality of glass core units 210. Buildup layers 211 may be provided above and/or below the glass core units 210. As described above, the interaction between the buildup layers 211 and the glass core units 210 may result in significant warpage or other damage (e.g., seware defects). When a seware defect occurs, the forces applied to the panel result in a horizontal splitting of the glass core. That is, the panel is split into a top side (comprising the top buildup layers and a top half of the glass core) and a bottom side (comprising the bottom buildup layers and a bottom half of the glass core). The top side and the bottom side warp in opposite directions of each other. Accordingly, embodiments, such as those shown in FIGS. 1A-1F may be used in order to prevent such defects.

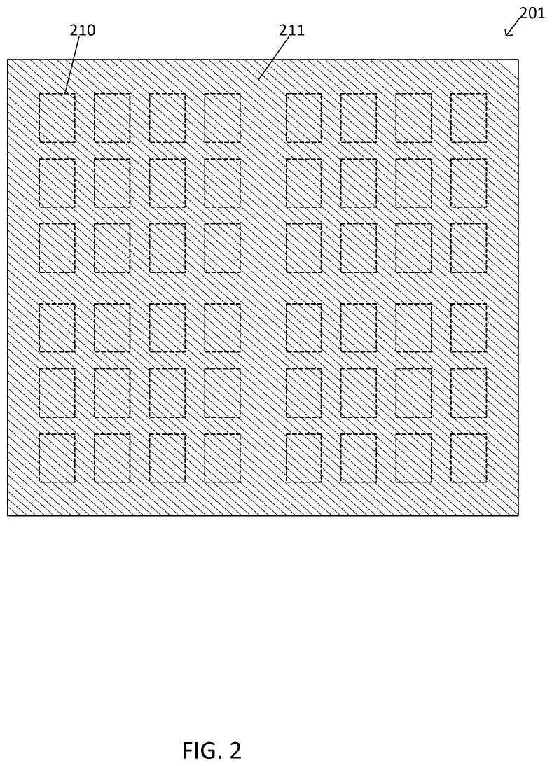

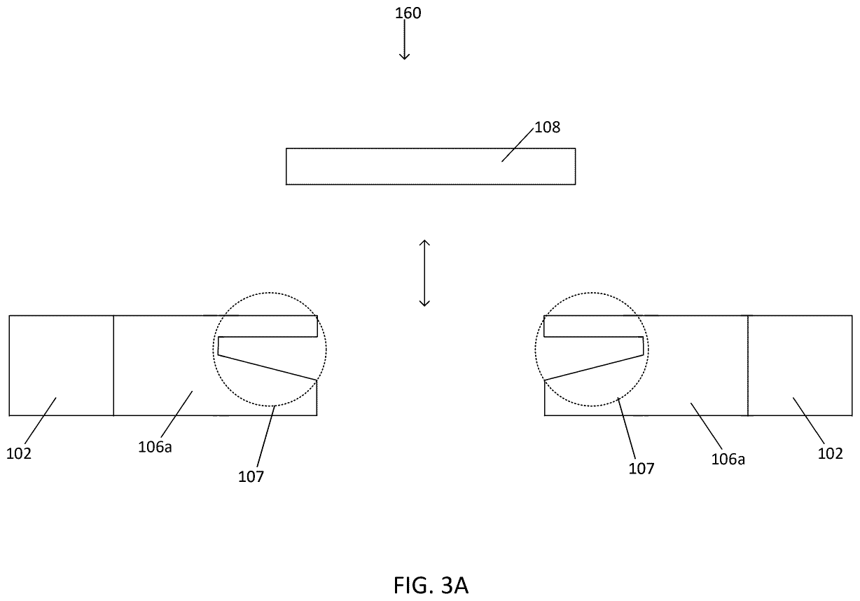

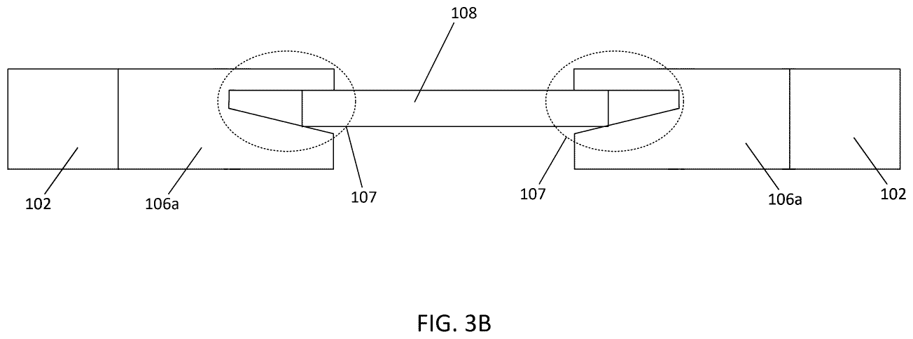

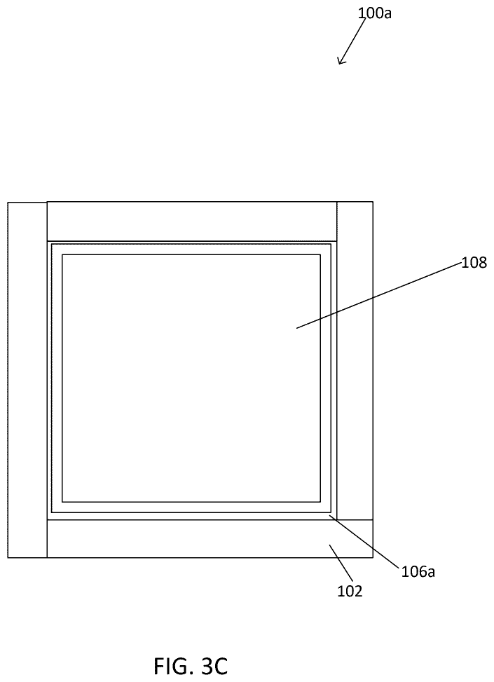

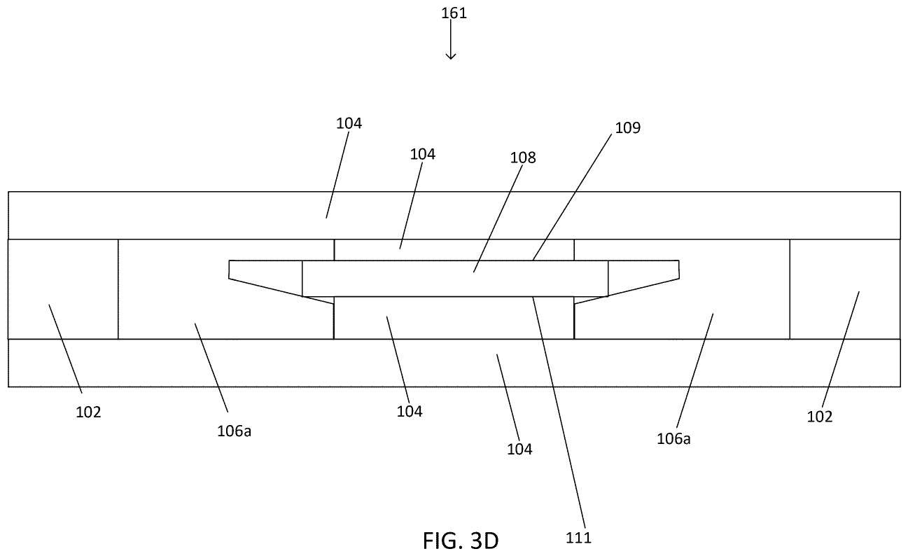

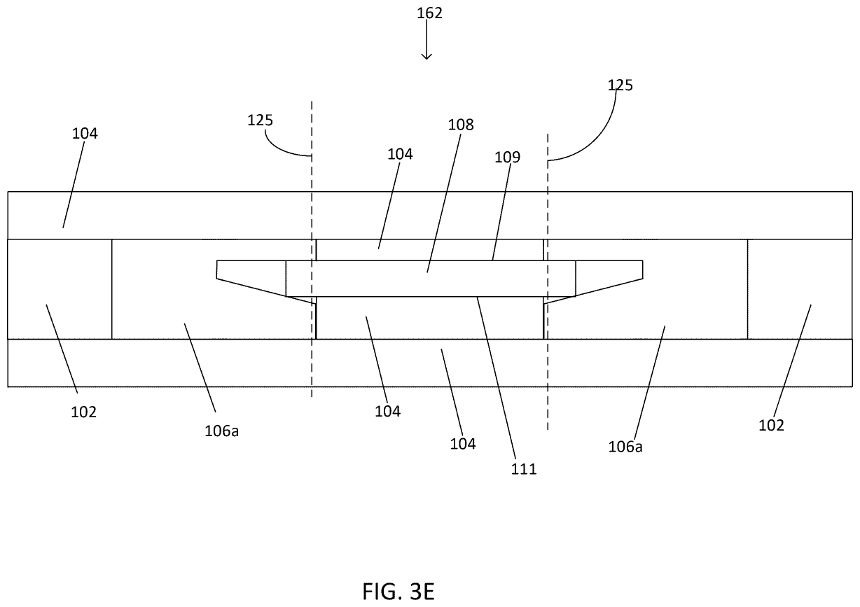

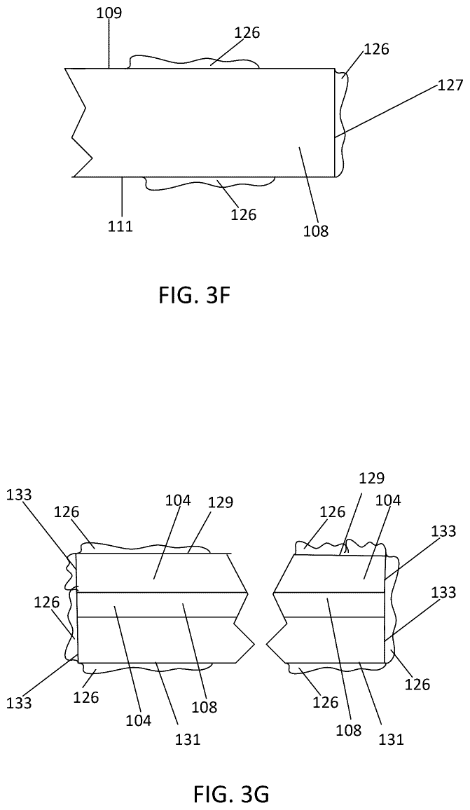

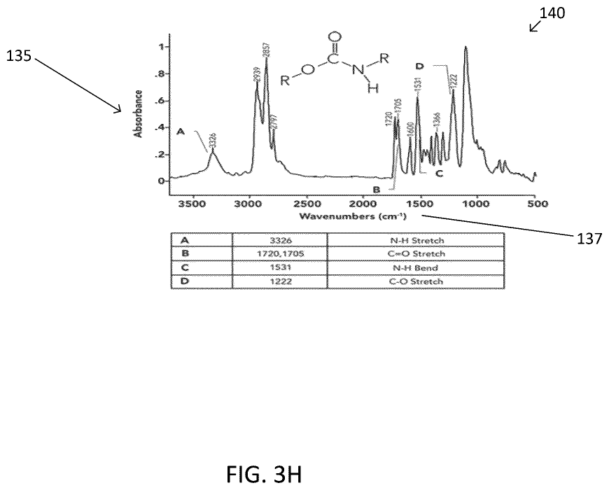

FIGS. 3A-3H depict methods of processing glass panel structures to form glass core package structures by utilizing the glass panel handling structures 106a of FIGS. 1A-1B, for example. FIG. 3A depicts a cross-sectional view of an attachment process 160 wherein a glass panel 108 may be placed within the lip wedge portion 107 of the glass panel handling structure 106a by using attachment process 160. In an embodiment, frame 102 may comprise a CCL frame, but may comprise any suitable frame 102, and is coupled to the glass panel handling structure 106a. The glass panel handling structure 106a may comprise a PU material, which acts as a shock absorber to prevent damage to the glass panel 108. In other embodiments, the glass panel handling structure 106a may comprise any suitable elastomeric material which can provide shock absorbing properties for the glass panel 108. The lip wedge portion 107 of the glass handling structure 106a holds the glass panel 108 in place. In an embodiment, the elastomeric glass handling structure 106a is capable of a 3D motion which acts as a sleeve for the glass panel 108 thus alleviating stress fracture in the glass panel 108.

In an embodiment, glass panel 108 may comprise a plurality of glass core units, a plurality of glass substrates or a glass quarter panel, wherein a plurality of package core units are distributed across the glass panel 108. The individual glass core units may be provided in a grid-like array. For example, the glass core units may be provided in an array that forms four quarter panels, with each quarter panel having twelve individual units. The use of glass panel level processing allows for improved throughput. That is, the plurality of glass core units may be fabricated and assembled substantially in parallel with each other.

FIG. 3B depicts a cross-sectional view of the glass panel handling apparatus 106a subsequent to the placement of the glass panel 108 within the lip portion 107 of the glass handling structure 106a. The glass handling structure 106a acts as a shock absorber which reduces or eliminates formation of defects in the glass panel.

FIG. 3C depicts a top view of the glass panel handling apparatus 100a wherein the glass panel 108 is surrounded by the glass handling structure 106a with the frame 102 coupled to the glass panel handling structure 106a. In an embodiment glass panel processing is handled with the glass panel handling apparatus 100a, but the rest of the process flow may utilize organic panel infrastructure. This greatly reduces the cost of glass core processing.

The glass panel handling structure 106a enables the use of a highly versatile shock absorber material, such as a polyurethane material for example which comprises highly tunable mechanical properties which can be tuned for a wide range of desirable material properties. In this manner, the glass panel handling structure 106a can be tuned for a particular application. In an embodiment, the glass panel handling structure 106a may comprise a soft plastic material or a foam finish material. The glass panel 108 is separated from the frame 102 by the glass panel handling structure 106a. In an embodiment, the glass panel handling structure 106a acts as a shock absorber as well as a glass panel edge protector and can be adjusted in 3D in order to allow the glass panel 108 to be locked in place.

FIG. 3D depicts a cross-sectional view of a process 161 wherein a buildup layer 104 is formed on a first side 109 and a second side 111 of the glass panel 108. The buildup layer formation process 161 may be accomplished by using any suitable processes and materials with which to form the buildup layers 104 on the first and second sides 109, 111 of the glass panel 108. In an embodiment, the buildup material 104 may be formed using standard buildup processing methods where the glass panel 108 is encapsulated by the buildup layer 104. In an embodiment, the buildup process can be performed by using standard lamination processes which may be complimentary with organic substrate lamination processes.

FIG. 3E depicts the handling structure 106a undergoing a removal process 162 wherein the glass panel 108 may be removed from the glass handling apparatus 100a at location 125 by either mechanical processes and/or singulation processes as are known in the art, including laser debonding, las skiving, or mechanical separation/dicing. The location and methods of removal may be tailored to the particular application.

FIG. 3F depicts a portion of the glass panel 108 subsequent to a singulation process wherein portions of the glass panel 108 may comprise a coating 126 from the glass panel handling structure 106a. Coating 126 may also be characterized as a residue. In an embodiment, the coating 126 may comprise the substantially same chemical composition as the PU material of the glass panel handling structure 106a, because portions of the PU material may remain on at least one of the sidewalls 127 or on the first or second sides 109, 111 of the glass panel 108 after glass panel 108 handling and build up layer 104 formation. Additionally, portions of the sidewalls 133 or top 129 or bottom 131 surfaces of the buildup layer 104 may comprise coating from the material of the glass handling structure 106a as shown in FIG. 3G. In an embodiment, a thickness of the coating 126 may range from about 100 nm to about 1 micron and the location of the coating 126 may vary depending on processing parameters.

FIG. 3H depicts a portion of a spectral analysis graph 140 of the coating 126 upon utilization of a spectral analysis measurement, as are known in the art. In an embodiment, an infrared (IR) spectral analysis may be performed on the coating 126, wherein absorbance 135 is shown on the Y axis and corresponding wave numbers 137 are shown on the X axis. Although FIG. 3G depicts an IR spectral analysis graph, any other suitable spectral or other suitable analysis may be utilized to identify the presence of the chemical composition of the coating 126.

As shown, the PU material of the glass handling structure 106a of FIG. A for example comprises a typical fingerprint of coating 126 wavenumbers as can be seen from the graph. For example, wavenumbers at approximately 3326, 1720, 1531 and 1222 identify portions of the coating 126 chemical composition, such as N—H stretch, carbon double bond stretch, N—H bend and C—O stretch respectively. Although FIG. 3H provides a representative example of a chemical analysis of the coating 126, any other analysis may be performed to identify the chemical composition of the residue as are known in the art.

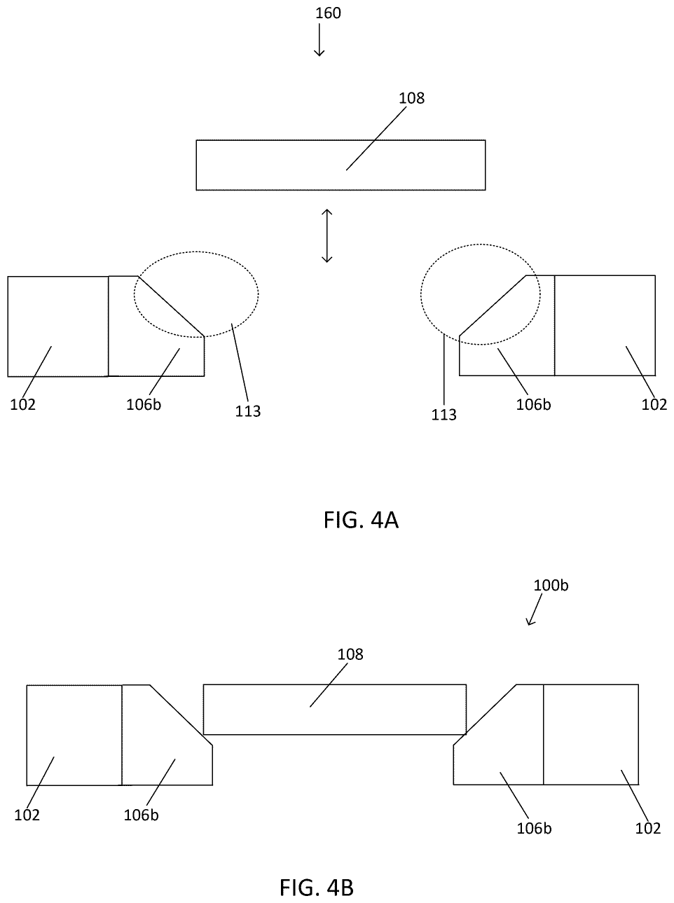

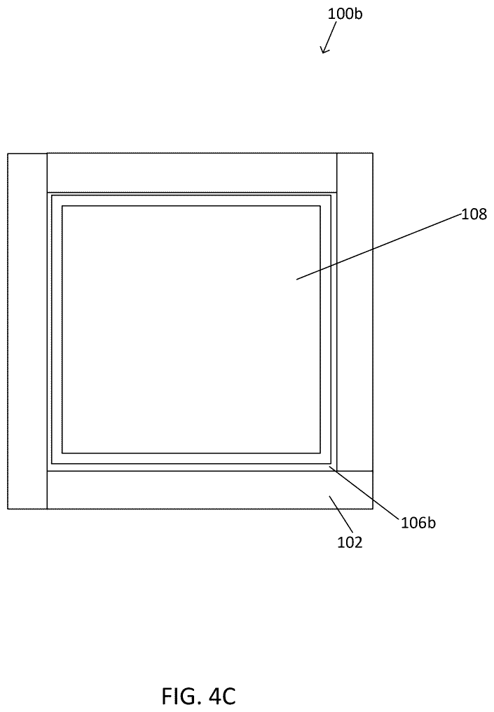

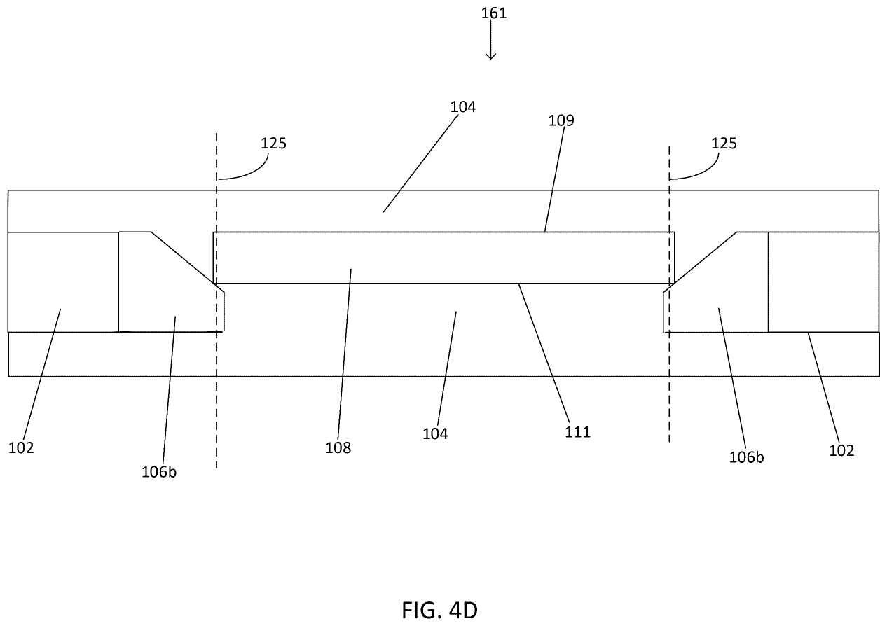

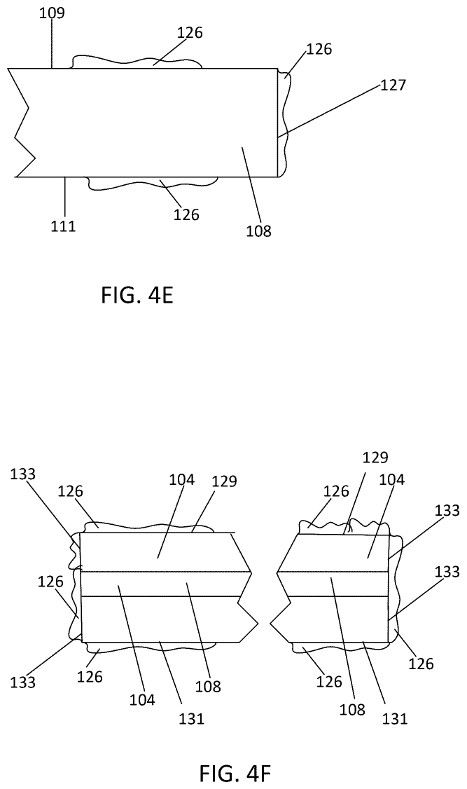

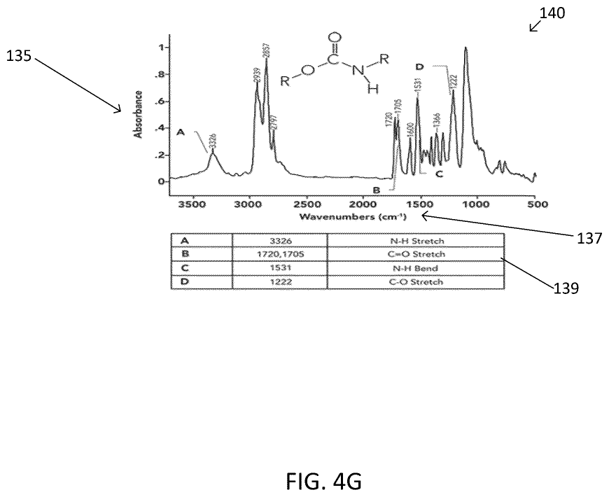

FIGS. 4A-4G depict methods of processing glass panel structures to form glass core package structures by utilizing the glass panel handling structures 106b of FIG. 1C, for example. FIG. 4A depicts a cross-sectional view of an attachment process 160 wherein a glass handling structure 106b may comprise a wedge portion 113 coupled to a frame 102. The frame 102 may comprise a CCL frame in an embodiment but may comprise any suitable frame type. The glass panel handling structure 106b may comprise a PU material, which acts as a shock absorber to prevent damage of a glass panel 108. The glass panel 108 may be placed on the wedge portion 113 of the glass panel handling structure 106a to hold the glass panel 108 in place utilizing the attachment/placement process 160. In an embodiment, the glass panel 108 may comprise a glass substrate or a glass quarter panel, wherein a plurality of glass core units are distributed across the glass panel 108. The plurality of glass core units may be fabricated and assembled substantially in parallel with each other. In an embodiment, the elastomeric glass handling structure 106b has a 3D motion which acts as a sleeve for the glass panel 108 thus alleviating stress fracture in the glass panel 108 during processing.

FIG. 4B depicts a cross-sectional view of the glass panel handling apparatus 100b subsequent to the placement of the glass panel 108 on the wedge portion 113 of the glass handling structure 106b. The glass handling structure 106b acts as a shock absorber which reduces or eliminates formation of defects in the glass panel 108.

FIG. 4C depicts a top view of the glass panel handling apparatus 100b wherein the glass panel 108 is surrounded by the glass handling structure 106b and the frame 102 is coupled to the outer side of the glass handling structure 106b. The glass panel handling structure 106b of the embodiments described herein enable the use of a highly versatile shock absorber material, such as a PU material for example which comprises highly tunable mechanical properties, such that the glass panel handling structure 106b can be tuned for a particular application. In an embodiment, the glass panel handling structure 106b may comprise a soft plastic material or a PU foam material. The glass core 108 is separated from the frame 102 by the glass panel handling structure 106b. In an embodiment, the glass panel handling structure 106b acts as a shock absorber as well as an edge protector and can be adjusted in order to allow the glass panel 108 to be locked in place.

FIG. 4D depicts a cross-sectional view of a process 161 wherein a buildup layer 104 is first formed on a first side 109 and on a second side 111 of the glass panel 108. The buildup layer formation process 162 may be accomplished by using any suitable processes and materials with which to form the buildup layers 104 on the first and second sides 109, 111 of the glass panel 108, and then a removal process (such as process 162 of FIG. 3E for example) may be employed which separates/removes the glass panel 108 from the glass handling structure 100b by either mechanical processes and/or singulation processes as are known in the art.

FIG. 4E depicts wherein portions of the glass panel 108 may comprise coating 126 from the glass handling structure 106c. In an embodiment, the coating 126 may comprise substantially same chemical composition as the glass handling structure 106c, and in an embodiment the coating 126 may comprise a PU material. In an embodiment, portions of the residue material may remain on at least one of the sidewalls 127, or the first or second sides 109, 111 of the glass panel 108 after glass panel 108 handling and build up layer 104 formation. Additionally, portions of the sidewalls 133 or top 129 or bottom 131 sides of the buildup layer 104 may comprise residue from the material of the glass handling structure 106b as shown in FIG. 4F.

FIG. 4G depicts a portion of a spectral analysis graph 140 of the coating 126 upon utilization of a spectral analysis measurement, as are known in the art. In an embodiment, an infrared (IR) spectral analysis may be performed on the coating 126, wherein an absorbance 135 is shown on the Y axis and a corresponding wave number 137 is shown on the X axis. FIG. 4G depicts an IR spectral graph, however any suitable spectral analysis or other suitable analysis may be utilized to identify the presence of the chemical composition of the coating 126.

As shown, the coating 126 may comprise a PU material for example, where typical fingerprint wavenumbers can be seen from the graph. For example, wavenumbers at approximately 3326, 1720, 1531 and 1222 identify portions of the coating 126 chemical composition, such as N—H stretch, carbon double bond stretch, N—H bend and C—O stretch respectively. Although FIG. 4H provides a representative example of a chemical analysis of the coating 126, any other analysis may be performed to identify the chemical composition of the residue as are known in the art.

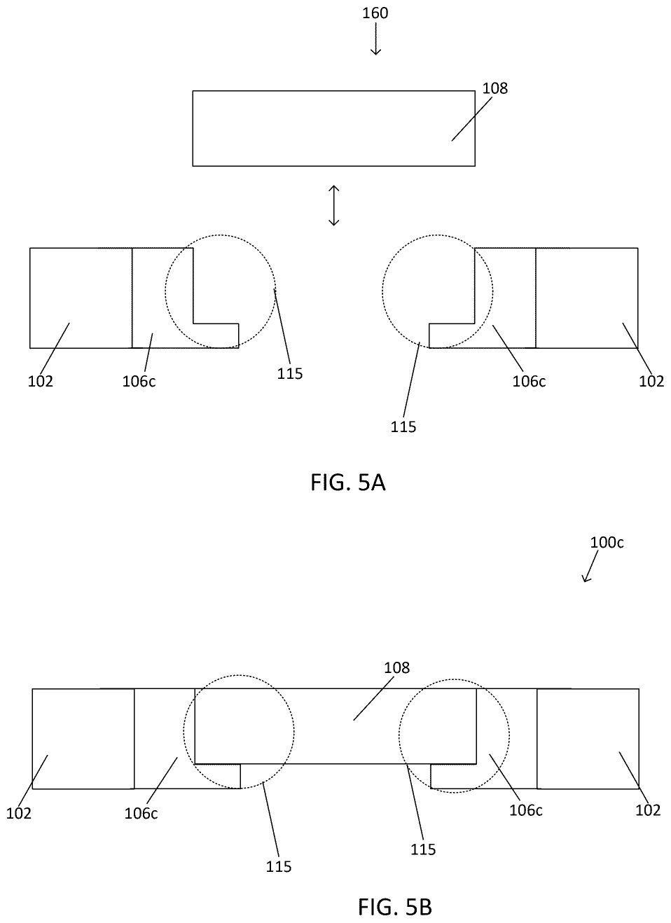

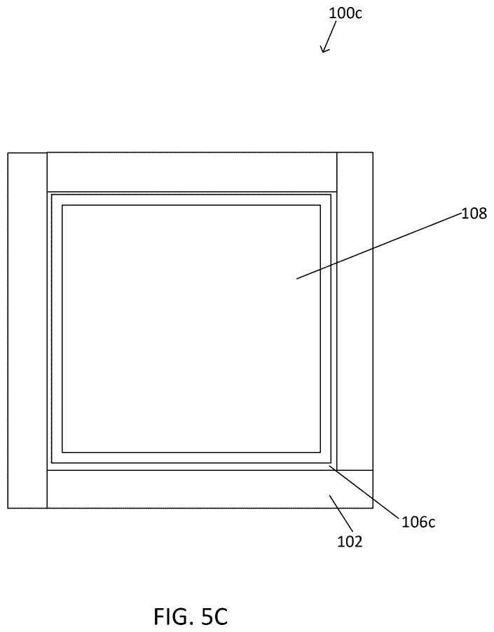

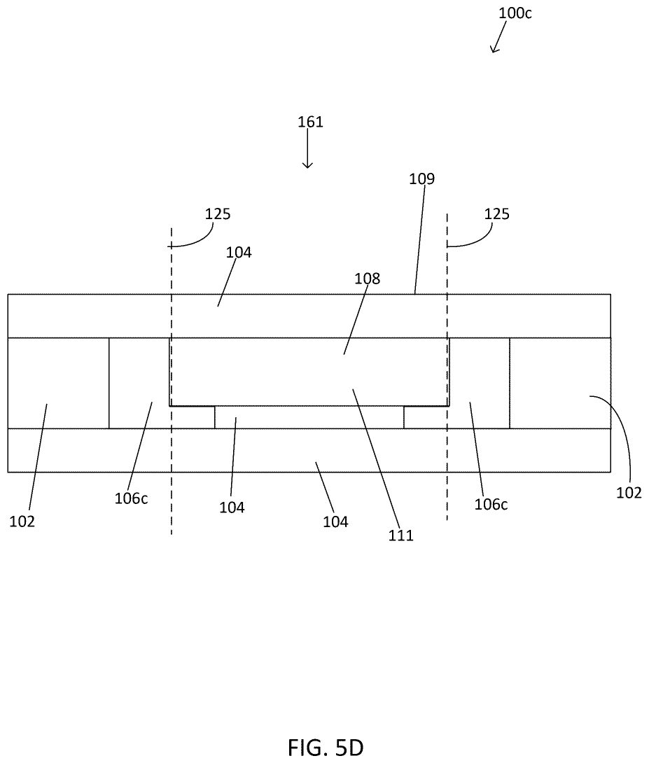

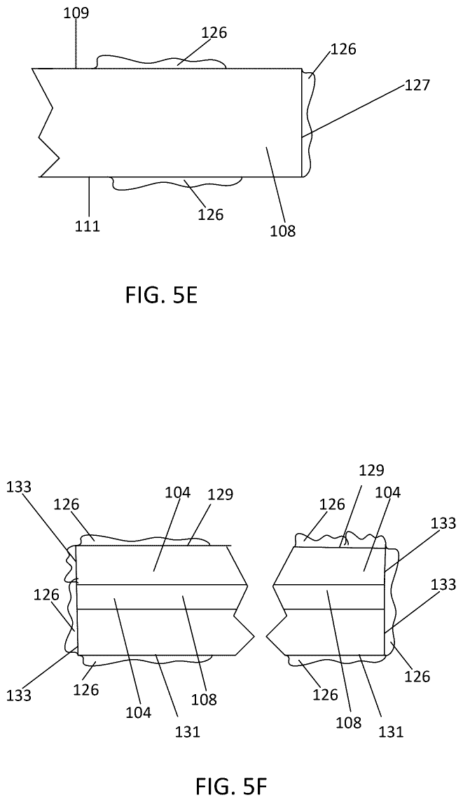

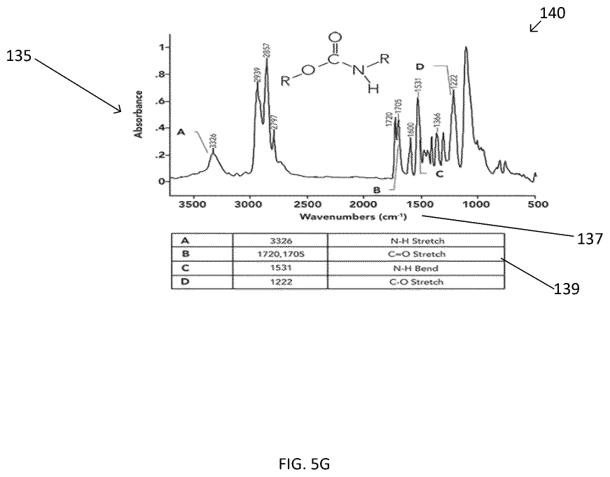

FIGS. 5A-5G depict methods of processing glass panel structures to form glass core package structures by utilizing the glass panel handling structures 106c of FIG. 1D, for example. FIG. 5A depicts a cross-sectional view of an attachment process 160 wherein a glass panel handling structure 106c may comprise an L shaped portion 115 coupled to a frame 102. The frame 102 may comprise a CCL frame but may comprise any suitable frame type. The glass panel handling structure 106c may comprise a PU material, which acts as a shock absorber to prevent damage to the glass panel 108 but may comprise any suitable material which provides shock absorption for glass panel 108. The glass panel 108 may be placed on the L shaped portion 115 of the glass panel handling structure 106c to hold the glass panel 108 in place utilizing the placement process 160.

In an embodiment, the glass panel 108 may comprise a glass unit substrate or a glass quarter panel, wherein a plurality of glass core units are distributed across the panel 108. The use of panel level processing of the embodiments herein allows for improved throughput since the plurality of glass core units may be fabricated and assembled substantially in parallel with each other. In an embodiment, the elastomeric glass panel handling structure 106c has a 3D motion which acts as a sleeve for the glass panel 108 thus alleviating stress fracture in the glass panel 108.

FIG. 5B depicts a cross-sectional view of the glass panel handling apparatus 100c subsequent to the placement of the glass panel 108 on the L shaped portion 115 of the glass panel handling structure 106c. The glass panel handling structure 106c acts as a shock absorber which prevents formation of defects in the glass panel 108.

FIG. 5C depicts a top view of the glass panel handling apparatus 100c wherein the glass panel 108 is surrounded by the glass handling structure 106c and the frame 102 is outside of the glass handling structure 106c. In an embodiment glass panel 108 processing is handled by the glass panel handling apparatus, but subsequent processing may utilize organic panel infrastructure. The glass panel 108 is separated from the frame 102 by the glass panel handling structure 106c. In an embodiment, the glass handling structure 106c acts as a shock absorber as well as an edge protector and can be adjusted in order to allow the glass panel 108 to be locked in place.

FIG. 5D depicts a cross-sectional view of a process 161 wherein a buildup layer 104 is first formed on a first side 109 and a second side 111 of the glass panel 108. The buildup layer formation process 162 may be accomplished by using any suitable processes and materials with which to form the buildup layers 104 on the first and second sides 109, 111 of the glass panel 108. In an embodiment, the buildup layers 104 may be formed by forming a liquid build up material on the first and second sides 109, 111 of the glass panel 108 followed by a curing process. After the curing process the interface between the glass panel 108 and the glass handling structure 100b may be locked in place. After the buildup process, the glass panel 108 may be separated/removed from the glass handling structure 100b at locations 125 by either mechanical processes and/or singulation processes as are known in the art. In an embodiment, such removal processes (such as process 162 of FIG. 3E for example) may be employed which separates/removes the glass panel 108 from the glass handling structure by either mechanical processes and/or singulation processes as are known in the art.

FIG. 5E depicts wherein portions of the glass panel 108 may comprise coating 126 from the glass handling structure 106c. In an embodiment, the coating 126 may comprise the substantially same chemical composition as the PU material of the structure 106c, because portions of the PU material may remain on at least one of the sidewalls 127 or the first or second sides 109, 111 of the glass panel 108 after glass panel 108 handling and build up layer 104 formation. Additionally, portions of the sidewalls 133 or top 129 or bottom 131 sides of the build up layer 104 may comprise residue from the material of the glass handling structure 106b as shown in FIG. 5F.

FIG. 5G depicts a portion of a spectral analysis graph 140 of the coating 126 upon utilization of a spectral analysis measurement, as are known in the art. In an embodiment, an infrared (IR) spectral analysis may be performed on the coating 126, wherein an absorbance 135 is shown on the Y axis and a corresponding wave number 137 is shown on the X axis. Although FIG. 5G depicts an IR spectral graph, however any suitable spectral or other suitable analysis may be utilized to identify the presence of the chemical composition of the coating 126.

As shown, the PU material of the glass handling structure 106c comprises a typical fingerprint of coating 126 wavenumbers as can be seen from the graph. For example, wavenumbers at approximately 3326, 1720, 1531 and 1222 identify portions of the coating 126 chemical composition, such as N—H stretch, carbon double bond stretch, N—H bend and C—O stretch respectively. Although FIG. 5H provides a representative example of a chemical analysis of the coating 126, any other analysis may be performed to identify the chemical composition of the residue as are known in the art.

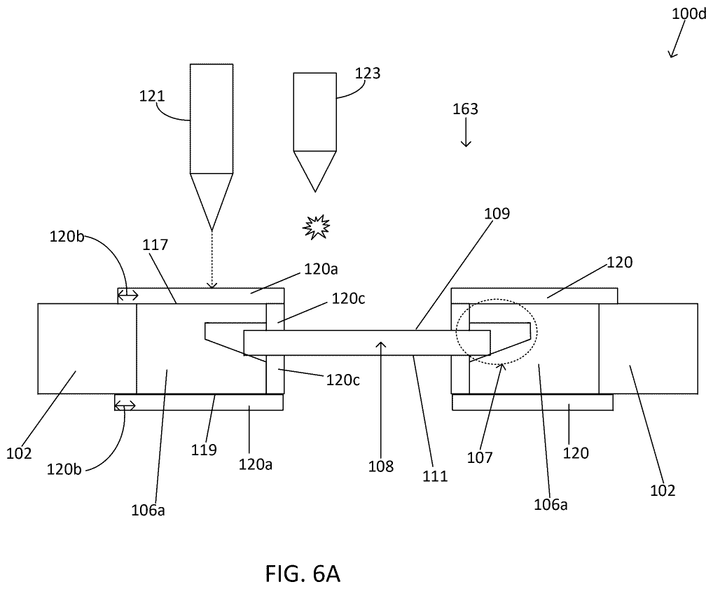

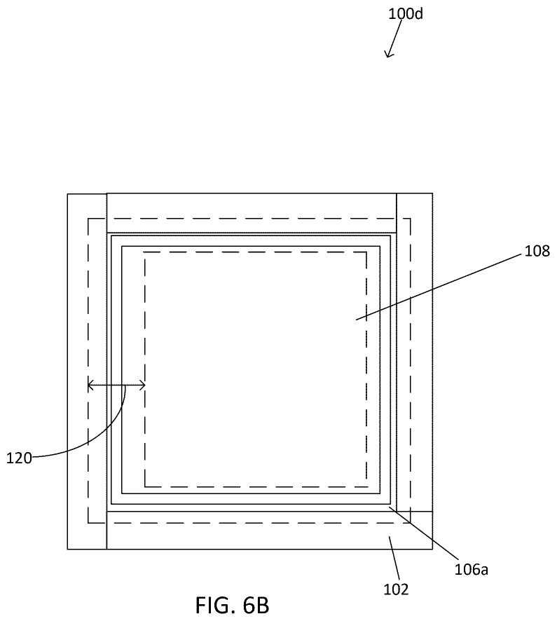

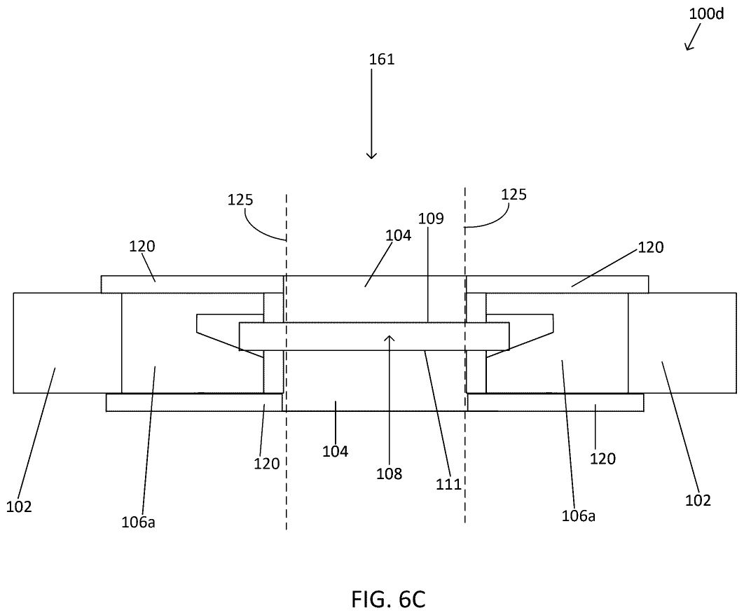

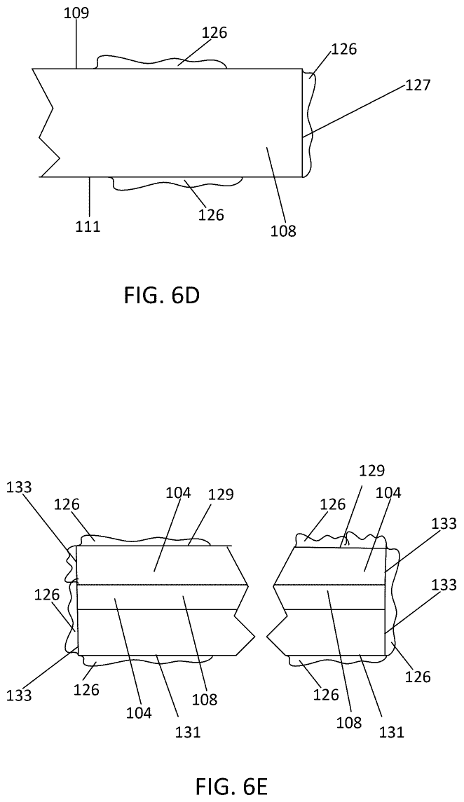

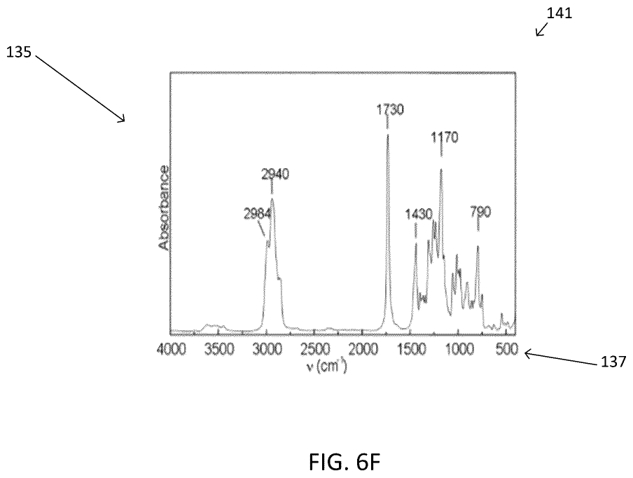

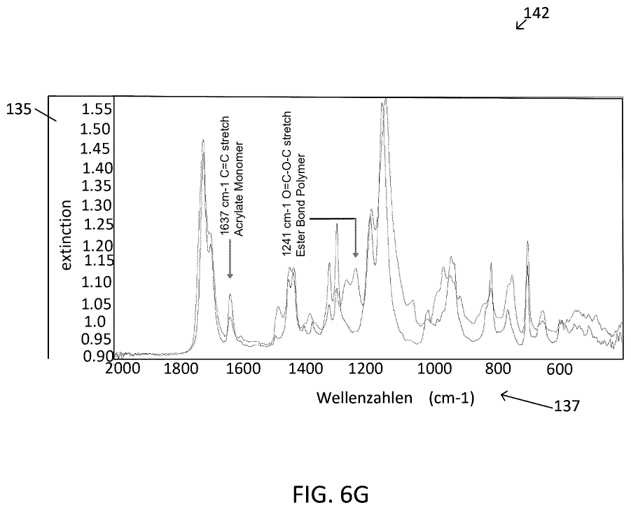

FIG. 6A depicts a cross-sectional view of a deposition process 163 wherein an adhesive material 120 is formed on portions of a glass panel handling apparatus 100d. The glass panel handling structure 106a may comprise an elastomer such as a polyurethane (PU) soft plastic or PU foam material. The glass panel handling structure 106a acts as a buffer for preventing fractographical defects on a glass panel 108 that is positioned within a lip portion 107 of the glass handling structure 106a. The glass panel handling structure 106a is coupled to the frame 102.

An adhesive 120 material may be formed by forming a first portion of a UV curable adhesive material 120a on a first side 117 and on a second 119 side of the glass handling structure 106a, forming a second portion 120b of the adhesive material 120 on a portion of the frame 102, and additionally forming a third portion 120c of the adhesive material 120 on peripheral portions of the glass panel 108. In an embodiment, the third portion 120c of the adhesive material 120 may be orthogonally coupled to the first portion 120a of the adhesive material 120 so that the third portion 120c is in physical contact with peripheral portions of the glass panel 108. In an embodiment, the adhesive material 120 may comprise an acrylic based adhesive material or an epoxy based adhesive material.

In an embodiment, the adhesive material 120 may comprise a methylmethacrylate, acrylate, or MMA) and may comprise a resin-based, two-part adhesive comprised of acrylic or methylacrylic polymers. In another embodiment, the adhesive 120 may comprise such materials as glycidyl polyether of a dihydric phenol, filler, a flexibilizer and a curing agent, preferably, a mixture of an amine hardener and a rigidifying tertiary amine catalyst. Enhancement of desirable physical properties may be obtained by admixing a silane or silicone adhesion promoter. A dispenser tool 121 may be used to dispense and form the adhesive material 120 on the first and second sides 117, 119 of the glass handling structure 106a as well as on portions of the glass panel 108 and frame 102. In embodiments, any of the glass panel handling structures 106a-106c may be coupled to the frame 102 and may hold the glass panel 108 in place prior to adhesive 120 formation. In an embodiment, the elastomeric glass handling structure 106a has a 3D motion which acts as a sleeve for the glass panel 108 thus alleviating stress fracture in the glass panel 108.

Subsequent to the dispensing of the adhesive material 120 on the glass handling structure 106a and on portions of the glass panel 108 and the frame 102, the adhesive 120 can be cured under a UV light for 15 seconds, utilizing a curing tool 123, in an embodiment. This can be followed up with a room temperature curing for 10 mins. Time and temperature can be optimized according to the particular application requirements.

FIG. 6B depicts a top view of the glass panel handling apparatus 100d wherein the glass panel 108 is surrounded by the glass handling structure 106a and the frame 102 is outside of the glass handling structure 106a. The adhesive material 120 is on portions of the frame 102, the glass panel 108 and the glass handling structure 106a. In an embodiment, subsequent to curing the adhesive material 120, the adhesive material 120 may be perforated using laser irradiation and mechanical separation techniques to remove the glass panel 108 from the frame 102.

FIG. 6C depicts a cross-sectional view of a process 161 wherein a build up layer 104 is first formed on a first side 109 and a second side 111 of the glass panel 108. The build up layer formation process 162 may be accomplished by using any suitable processes and materials with which to form the build up layers 104 on the first and second sides 109, 111 of the glass panel 108. Subsequently, the glass panel 108 may be removed at locations 125 (or at any other locations as are advantageous to the particular application) from the glass panel handling structure 100d by either mechanical processes and/or singulation processes as are known in the art.

FIG. 6D depicts portions of the glass panel 108, subsequent to singulation processing (not shown) that may comprise coating 126 from the glass handling structure material 106a and the adhesive material 120. In an embodiment, the coating 126 may comprise the substantially same chemical composition as the PU material of the structure 106c, because portions of the PU material may remain on at least one of the sidewalls 127, or the first or second sides 109, 111 of the glass panel 108 after glass panel 108 handling and build up layer 104 formation. Residue may also comprise the chemical composition of the adhesive material 120. Additionally, portions of the sidewalls 133 or top 129 or bottom 131 surfaces of the buildup layer 104 may comprise residue from the material of the glass handling structure 106a as well as from the adhesion material as shown in FIG. 6E. Examples of the spectral analysis of the PU material can be seen in FIG. 5G, for example.

FIG. 6F depicts a portion of a spectral analysis graph 141 of the coating 126 upon utilization of a spectral analysis measurement, as are known in the art. A portion of the coating 126 may comprise the adhesive material 120. In an embodiment, an infrared (IR) spectral analysis may be performed on the coating 126, wherein an absorbance 135 is shown on the Y axis and a corresponding wave number 137 is shown on the X axis. Although FIG. 6F depicts an IR spectral graph, however any suitable spectral or other suitable analysis may be utilized to identify the presence of the chemical composition of the coating 126 comprising the adhesive material 120.

As shown, an epoxy based adhesive material 120 portion of the coating 126 comprises a typical fingerprint of wavenumbers as can be seen from the graph. The presence of an absorption band located at 790 cm−1 corresponds to the stretching C—O—C of ethers, bands at (1100 cm−1) and the C═O stretching (1730 cm−1) of esters are representative of epoxy resin adhesive materials. Although FIG. 6F provides a representative example of a chemical analysis of the epoxy based adhesive material 120, any other analysis may be performed to identify the chemical composition of the residue as are known in the art.

FIG. 6G depicts a Fourier transform (FT) IR spectra of an acrylic based adhesive material 120 portion of the coating 126, and comprises a typical fingerprint of wavenumbers as can be seen from the graph 142. The presence of acrylic groups in the IR spectra are indicated by the signal at 1637 cm−1 is characteristic of the C═C-bond of the acrylate monomer. Additionally, the signal at 1241 cm−1 is characteristic of the O═C—O—C ester bond in the polymeric acrylate that is formed during the adhesive curing.

Although FIG. 6G provides a representative example of a chemical analysis of an acrylic based portion of the adhesive material 120, coating 126, any other analysis may be performed to identify the chemical composition of the residue as are known in the art.

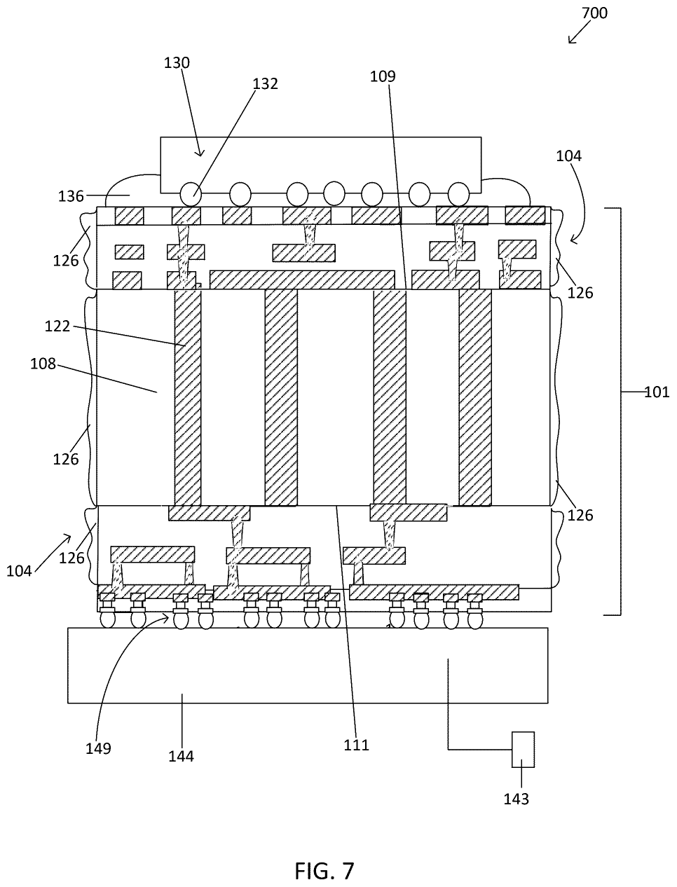

FIG. 7 depicts an IC package structure 700, such as a package structure including a glass core 108 according to embodiments herein. The package structure 700 may be similar to the portions of the package structures depicted in FIGS. 3G, 4F, 5F or FIG. 6E for example. Buildup layers 104 are on first and second sides 109, 111 of the glass core 108, wherein through glass vias 122 are coupled to a die 130 within the package structure 700. In some embodiments, the die 130 may comprise chiplet structures which may comprise components of a system on a chip (SOC) structure. In an embodiment the glass core 108 may include a portion of an interposer. coating 126 from either the adhesive material or the glass panel handling structures may be present on sidewalls (or other surfaces) of the buildup layers 104 and/or sidewalls of the glass core 108. The coating 126 may or may not be present in all locations depicted in FIG. 7. The glass core 108 may comprise any suitable substrate with which to attach die and build a package structure thereupon. In an embodiment the core 108 may provide mechanical support and provide electrical communication within a package structure 700 and between devices coupled with such a package structure 700.

Any number of die/devices 130 may be coupled to the glass core 108. The package substrate 101 (comprising the core 108 and build up layers 104) and device(s) 130 may be coupled to a board 144, such as a printed circuit board, in an embodiment. The board 144 may be coupled to the package substrate 101 through solder structures 149 in an embodiment. A power supply 143, which may comprise any suitable power supply as known in the art, may be coupled to die 130 via IC package substrate 101, in an embodiment. Solder interconnect structures 132 may couple the die 130 to the substrate 101. An underfill material 136 may surround the solder structures 132, in an embodiment.

Discussion now turns to operations for assembling and/or fabricating the discussed structures.

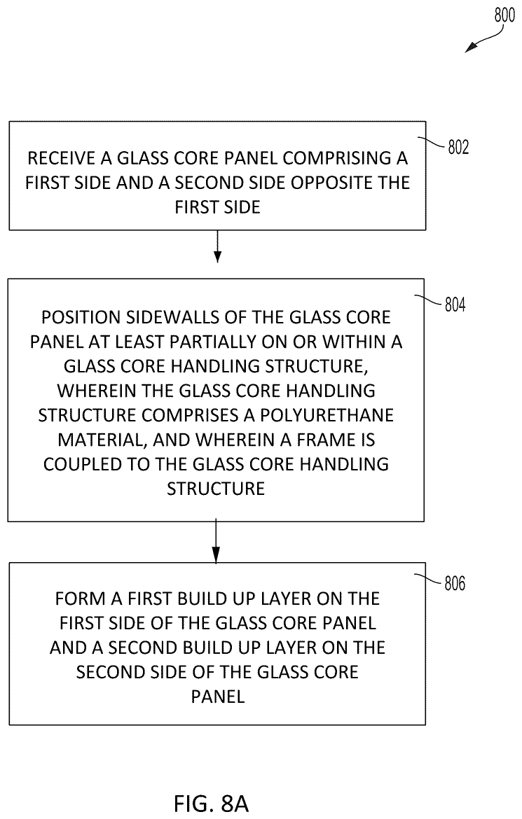

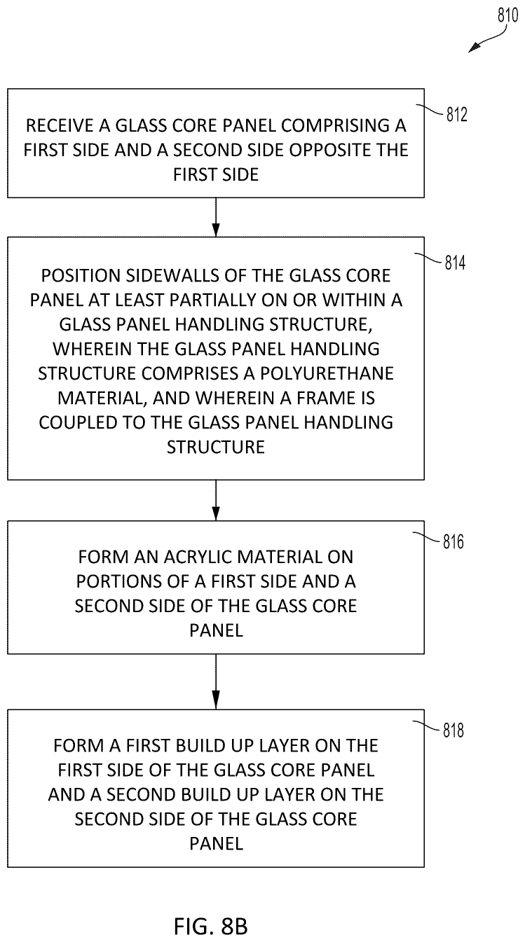

FIG. 8A is a flow chart of a process 800 of fabricating package structures, such as a package substrate comprising a glass core with a coating on at least the sidewalls of the glass core, according to some embodiments. For example, process 800 may be used to fabricate any of the microelectronic IC glass core package structures of FIGS. 3G, 4F, 5F, 6E, or FIG. 7, for example.

As set forth in block 802, a glass core panel is received comprising a first side and a second side opposite the first side. In an embodiment, the glass core panel may comprise a plurality of glass substrates as described in FIG. 2 for example, and may comprise a plurality of glass substrate units which may be singulated subsequent to buildup layer formation thereupon, or the glass core panel may comprise a glass quarter panel comprising a plurality of glass substrate units.

As set forth in block 804, sidewalls of the glass core panel may be positioned at least partially on or within a glass core handling structure. The glass core handling structure may comprise a polyurethane material comprising a specific shape that is coupled to a frame. In an embodiment, the frame may comprise a copper clad laminate frame, however any suitable frame may be coupled to the glass core handling structure.

The glass panel handling structure may comprise any suitable shape that provides a support mechanism with which to position the glass core panel thereupon. The glass panel handling structure provides stability and shock absorption properties due to its chemical composition. In an embodiment, the glass panel handling structure may comprise a polymer material such as a polyurethane material. Such elastomeric material may provide a sleeve structure in an embodiment so that the glass core panel can move in a 3D pattern during processing, such as during the formation of buildup material upon top and bottom surfaces of the glass core panel.

In another embodiment, the glass panel handling structure may comprise a wedge or an L shape structure with which to receive the glass core panel. Again, the glass panel handling structure provides a shock absorbing material which serves to reduce glass stress defects during buildup process upon surfaces of the glass core panel. In another embodiment, the glass panel handling structure may further comprise an adhesion material, such as an epoxy or acrylic based adhesive material on top and bottom surfaces of the glass panel handling structure as well as on portions of the frame adjacent to the top and bottom surfaces of the glass panel handling structure.

At block 806, a first build up layer may be formed on the first side of the glass core panel and a second build up layer may be formed on the second side of the glass core panel. Because the glass panel handling structure is providing stability and shock absorption for the glass panel during build up layer formation, stress defects are greatly reduced or eliminated within the glass panel. The build up layer may comprise any suitable build up layer material, such as dielectric materials and conductive materials dispersed within. Subsequent to singulation processing, glass core panel sidewalls as well as sidewalls of the build up materials may comprise a residue or coating. The coating may comprise the chemical composition of the polyurethane material of the glass panel handling structure and/or the chemical composition of the adhesive material. The coating may be identified by utilizing spectral analysis for example.

One or more die may be attached on the build-up layer subsequent to a singulation process to form a package structure as shown in FIG. 7 for example. The die may comprise a central processing unit (CPU) or a field programmable gate array (FPGA) die, for example or may comprise any suitable logic die for the particular application. The die may be attached utilizing any suitable die attach process, as are known in the art. The die may be coupled to the package substrate via solder structures coupled to conductive contact structures as are known in the art.

FIG. 8B is a flow chart of a process 810 of fabricating package structures, such as a package substrate comprising a glass core with a coating on at least the sidewalls of the glass core, according to some embodiments. For example, process 810 may be used to fabricate any of the microelectronic IC package structures of FIG. 6F or 7, for example.

As set forth in block 812, a glass core panel is received comprising a first side and a second side opposite the first side. In an embodiment, the glass core panel may comprise a glass panel substrate as described in FIG. 2 for example comprising a plurality of glass substrate units which may be singulated subsequent to build up layer formation thereupon.

As set forth in block 814, sidewalls of the glass core panel may be positioned at least partially on or within a glass panel handling structure. The glass panel handling structure may comprise a polyurethane material comprising a specific shape that is coupled to a frame. In an embodiment, the frame may comprise a copper clad laminate frame, however any suitable frame may be coupled to the glass core handling structure.

The glass panel handling structure may comprise any suitable shape that provides a support mechanism with which to position the glass core panel thereupon. In an embodiment, the glass panel handling structure may comprise a polymer material such as a polyurethane material. Such elastomeric material may provide a shock absorbing material which serves to reduce glass stress defects during buildup formation process upon surfaces of the glass core panel.

As set forth in block 816, an adhesive material may be formed on portions of a first side and a second side of the glass core panel, as well as on portions of the glass panel handling structure and on portions of the frame as shown in FIG. 6A, for example. In an embodiment, the adhesion material, may comprise an epoxy or an acrylic based adhesive material. Post formation of the adhesive material, the adhesive material can be cured under a UV light using a UV tool for 15 seconds in an embodiment. This can be followed up with a room temperature curing for 10 mins. Subsequent to build up layer formation the adhesive material may be perforated using laser irradiation and simple mechanical separation of the glass core panel from the frame in an embodiment.

As set forth in block 818, a first build up layer may be formed on the first side of the glass core panel and a second build up layer on the second side of the glass core panel. Because the glass panel handling structure is providing stability and shock absorption for the glass core panel during build up layer formation, stress defects are greatly reduced or eliminated within the glass core panel. The build up layers may comprise any suitable build up layer material, such as dielectric materials and conductive materials dispersed within. The build up layer may comprise a liquid build up material which has been cured, in an embodiment.

Subsequent to singulation processing, glass core panel sidewalls as well as sidewalls of the build up materials may comprise a residue or coating. The coating may comprise the chemical composition of the polyurethane material of the glass panel handling structure and/or the chemical composition of the adhesive material. The coating may be identified by utilizing spectral analysis for example.

One or more die may be attached on the build-up layers to form a package structure as shown in FIG. 7 for example. The die may comprise a central processing unit (CPU) or a field programmable gate array (FPGA) die, for example or may comprise any suitable logic die for the particular application. The die may be attached utilizing any suitable die attach process, as are known in the art.

By reducing compressive stress vectors applied to the glass core panel by the overlying buildup layers, catastrophic defects, can be reduced or eliminating specially at the panel level. Seware defects may be prevented by utilizing the glass panel handling structures of the embodiments herein. Additionally, fabrication costs are reduced by utilizing glass core panel handling tools and then subsequently utilizing organic panel infrastructure tools. The use of a highly versatile shock absorber material with highly tunable mechanical properties enables cost efficient glass panel hybrid processing.

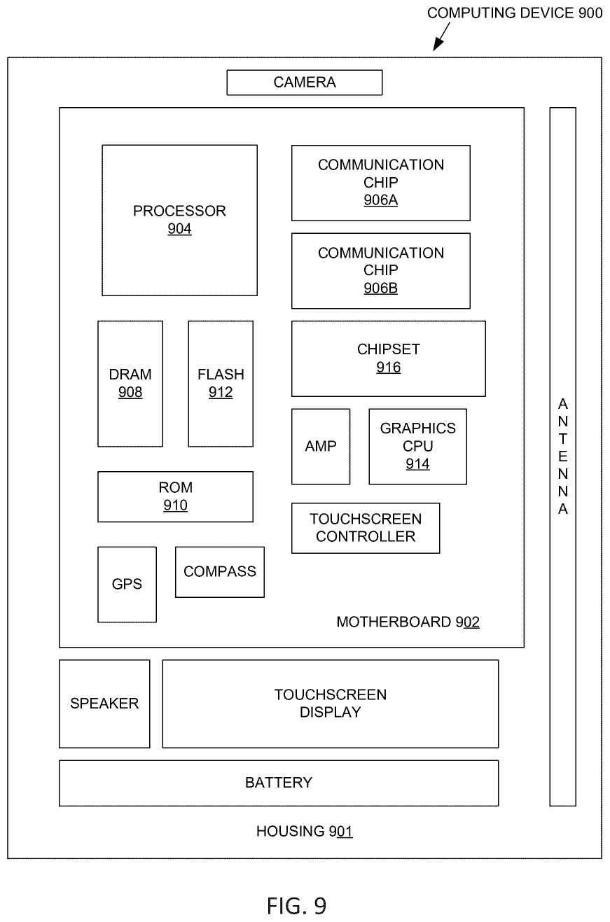

FIG. 9 illustrates an electronic or computing device 900 in accordance with one or more implementations of the present description. The computing device 900 may include a housing 901 having a board 902 disposed therein. The computing device 900 may include a number of integrated circuit components, including but not limited to a processor 904, at least one communication chip 906A, 906B, volatile memory 908 (e.g., DRAM), non-volatile memory 910 (e.g., ROM), flash memory 912, a graphics processor or CPU 914, a digital signal processor (not shown), a crypto processor (not shown), a chipset 916, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 902. In some implementations, at least one of the integrated circuit components may be a part of the processor 904.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. At least one of the integrated circuit components may include a glass core package structure with a glass panel handling structure coating on at least one of sidewalls of a build up layer or sidewalls of a glass core.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure. It is understood that the subject matter of the present description is not necessarily limited to specific applications illustrated in FIGS. 1-9. The subject matter may be applied to other integrated circuit devices and assembly applications, as well as any appropriate electronic application, as will be understood to those skilled in the art.

The following examples pertain to further embodiments and specifics wherein the examples may be used anywhere in one or more embodiments, wherein a first example is an apparatus, comprising a package substrate comprising a buildup layer, and a glass core comprising a layer of glass on the buildup layer, the glass core comprising a first side and a second side opposite the first side, a conductor within a through glass via (TGV) extending from the first side to the second side, and a sidewall extending between the first side and the second side, wherein at least a portion of the sidewall comprises a coating, wherein the coating comprises a polymer.

In second examples, the first example further comprises wherein the coating comprises one or more of a polyurethane material, an epoxy adhesive material or an acrylic adhesive material.

In third examples, wherein example 2 further comprises wherein the coating comprises the polyurethane material, the polyurethane material comprising a polyurethane foam comprising at least one of a polyol, a diisocyanates, a blowing agent, a surfactant, a catalysts or a curative.

In fourth examples, wherein example 2 further comprises wherein the coating comprises the polyurethane material, the polyurethane material comprising a polyurethane plastic comprising at least one of isocyanates, polyols, or additives.

In fifth examples, wherein any one of examples 1-4 further comprises wherein a spectral graph of the coating comprises a spectral graph of a polyurethane material, the spectral graph comprising one or more of a N—H stretch, a C═O stretch, a N—H in-plane bend, or a C—O stretch.

In sixth examples, wherein any one of examples 1-5 further comprises wherein at least one of the first side or the second side of the glass core comprises the coating.

In seventh examples, wherein any one of examples 1-6 further comprises wherein the conductor comprises copper or a copper alloy, and wherein the glass layer comprises one or more of aluminosilicate, borosilicate, an alumino borosilicate, silica, or a fused silica.

In eighth examples, wherein examples 7 further comprises wherein central portions of the first side and the second side of the glass core are free of the coating, and wherein the coating is on peripheral portions of the second side of the glass core.

In nineth examples, wherein examples 8 further comprises wherein the first side is entirely free of the coating.

In tenth examples, wherein any one of examples 1-9 further comprises wherein the coating is on a portion of a sidewall of the buildup layer.

In eleventh examples, wherein any one of examples 1-9 further comprises further comprising a die coupled to the TGV, and a power supply is coupled to the die.

A twelfth example is an apparatus comprising a package substrate comprising a glass core comprising a glass layer, a first build up layer on a first side of the glass core and a second build up layer on a second side of the glass core, an adhesive material on a sidewall of the glass core, the adhesive material comprising an epoxy material or an acrylic material; and a conductor within a through glass via (TGV) extending through the glass core.

In thirteenth examples, the twelfth example further comprises wherein the adhesive material comprises a thickness of not less than 100 nm and not more than 1 micron.

In fourteenth examples, wherein any one of examples 12-13 further comprises wherein at least one of the first side or the second side comprises the adhesive material.

In fifteenth examples, wherein any one of examples 12-14 further comprises wherein the adhesive material comprises at least one of a photo-initiator, a cross linking agent, a viscosity regulator or a resin.

In sixteenth examples, wherein any one of examples 12-15 further comprises a die coupled to the TGV, and a power supply is coupled to the die.

Example seventeen is a method comprising receiving a glass core panel comprising a first side and a second side opposite the first side, positioning sidewalls of the glass core panel at least partially on or within a glass panel handling structure, wherein the glass panel handling structure comprises a polyurethane material, and wherein a copper clad laminate (CCL) frame is coupled to the glass panel handling structure, and forming a first build up layer on the first side of the glass core panel and a second build up layer on the second side of the glass core panel.

In eighteenth examples, the seventeenth example further comprises wherein the glass panel handling structure comprises a wedge shape, and further comprising separating the CCL frame from the glass panel handling structure.

In nineteenth examples, wherein any one of examples 17-18 further comprises wherein the glass panel handling structure comprises an L shape, and wherein forming the first build up layer on the first side of the glass core panel and forming the second build up layer on the second side of the glass core panel comprises dispensing a liquid build up material and curing the liquid build up material.

In twentieth examples, wherein any one of examples 17-19 further comprises forming a curable adhesive material on a surface of the CCL frame and on a surface of the glass core handling structure, wherein a portion of the curable adhesive material is in contact with the glass core panel.

In twenty-first examples wherein any one of examples 17-20 further comprises wherein the glass panel handling structure comprises a lip wedge shape.

In twenty-second examples wherein any one of examples 17-21 further comprises wherein the glass panel handling structure comprises a lip wedge shape.

In twenty-third examples wherein any one of examples 20-22 further comprises wherein the curable adhesive material comprises an epoxy material or an acrylic material.

In twenty-fourth examples wherein any one of examples 17-23 further comprises wherein the glass panel handling structure is capable of three-dimensional adjustments of the glass core panel.

In twenty-fifth examples wherein any one of examples 17-24 further comprises wherein the glass core panel comprise a plurality of glass core units.

It will be recognized that principles of the disclosure are not limited to the embodiments so described but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
a package substrate comprising a buildup layer; and
a glass core comprising a layer of glass on the buildup layer, the glass core comprising:
a first side and a second side opposite the first side;
a conductor within a through glass via (TGV) extending from the first side to the second side; and
a sidewall extending between the first side and the second side, wherein at least a portion of the sidewall comprises a coating, wherein the coating comprises a polymer.

2. The apparatus of claim 1, wherein the coating comprises one or more of a polyurethane material, an epoxy adhesive material or an acrylic adhesive material.

3. The apparatus of claim 2, wherein the coating comprises the polyurethane material, the polyurethane material comprising a polyurethane foam comprising at least one of a polyol, a diisocyanates, a blowing agent, a surfactant, a catalysts or a curative.

4. The apparatus of claim 2, wherein the coating comprises the polyurethane material, the polyurethane material comprising a polyurethane plastic comprising at least one of isocyanates, polyols, or additives.

5. The apparatus of claim 1, wherein a spectral graph of the coating comprises a spectral graph of a polyurethane material, the spectral graph comprising one or more of a N—H stretch, a C═O stretch, a N—H in-plane bend, or a C—O stretch.

6. The apparatus of claim 1, wherein at least one of the first side or the second side of the glass core comprises the coating.

7. The apparatus of claim 1, wherein the conductor comprises copper or a copper alloy, and wherein the layer of glass comprises one or more of aluminosilicate, borosilicate, an alumino borosilicate, silica, or a fused silica.

8. The apparatus of claim 7, wherein central portions of the first side and the second side of the glass core are free of the coating, and wherein the coating is on peripheral portions of the second side of the glass core.

9. The apparatus of claim 8, wherein the first side is entirely free of the coating.

10. The apparatus of claim 1, wherein the coating is on a portion of a sidewall of the buildup layer.

11. The apparatus of claim 1, further comprising a die coupled to the TGV, and a power supply is coupled to the die.

12. An apparatus, comprising:
a package substrate comprising:
a glass core comprising a glass layer;
a first build up layer on a first side of the glass core and a second build up layer on a second side of the glass core;
an adhesive material on a sidewall of the glass core, the adhesive material comprising an epoxy material or an acrylic material; and
a conductor within a through glass via (TGV) extending through the glass core.

13. The apparatus of claim 12, wherein the adhesive material comprises a thickness of not less than 100 nm and not more than 1 micron.

14. The apparatus of claim 12, wherein at least one of the first side or the second side comprises the adhesive material.

15. The apparatus of claim 12, wherein the adhesive material comprises at least one of a photo-initiator, a cross linking agent, a viscosity regulator or a resin.

16. The apparatus of claim 12, further comprising a die coupled to the TGV, and a power supply is coupled to the die.

17. A method, comprising:
receiving a glass core panel comprising a first side and a second side opposite the first side;
positioning sidewalls of the glass core panel at least partially on or within a glass panel handling structure, wherein the glass panel handling structure comprises a polyurethane material, and wherein a copper clad laminate (CCL) frame is coupled to the glass panel handling structure; and
forming a first build up layer on the first side of the glass core panel and a second build up layer on the second side of the glass core panel.

18. The method of claim 17, wherein the glass panel handling structure comprises a wedge shape, and further comprising separating the CCL frame from the glass panel handling structure.

19. The method of claim 17, wherein the glass panel handling structure comprises an L shape, and wherein forming the first build up layer on the first side of the glass core panel and forming the second build up layer on the second side of the glass core panel comprises dispensing a liquid build up material and curing the liquid build up material.

20. The method of claim 17, further comprising forming a curable adhesive material on a surface of the CCL frame and on a surface of the glass panel handling structure, wherein a portion of the curable adhesive material is in contact with the glass core panel.
